(19) United States
(12) Patent Application Publication
(10) Pub. No.: US 2022/0236194 A1
(43) Pub. Date: Jul. 28, 2022

(54) Apparatus for Aiding Manufacturing of Optoelectronic Device

(71) Applicant: Nippon Telegraph and Telephone Corporation, Tokyo (JP)

(72) Inventors: Nobuhiro Nunoya, Musashino-shi, Tokyo (JP); Josuke Ozaki, Musashino-shi, Tokyo (JP)

(21) Appl. No.: 17/608,512

(22) PCT Filed: May 28, 2019
(86) PCT No.: PCT/JP2019/021140

§ 371 Date: Nov. 3, 2021

(51) Int. Cl. G01N 21/95; G01N 21/956; H01L 21/66

(52) U.S. Cl. CPC G01N 21/9501; G01N 2021/95615; H01L 22/12; G01N 21/95607

(57) ABSTRACT

Provided is a manufacturing support apparatus capable of manufacturing an optoelectronic device of improved characteristics with a low cost and a high yield rate. An inspection apparatus outputs to a server serving as a manufacturing support apparatus results obtained by performing defect inspections in different steps that may relate to the occurrence of defect determining a defective item in a primary process of device manufacturing. In the server, defect inspection result acquisition units acquire inspection results in respective steps, and a database separately stores the inspection results of the respective steps. By comparing defect information included in the inspection results obtained in the plurality of steps and the reference information indicating an inspection result of the normal state, a data processing control unit of the server determines whether an identical defect is indicated. When the determination result indicates the identical defect or a change in the state of a defect, the inspection result data at the time is provided as the record data for a device inspection performed later.

### TECHNICAL FIELD

The present invention relates to an optoelectronic device manufacturing support apparatus that are used to manufacture an optoelectronic device formed by using a semiconductor substrate, a wafer, or the like.

### BACKGROUND ART

During the conventional manufacturing process of semiconductor devices, wafers are visually inspected to measure the amount of dust consisting of foreign matters attached to the wafers. When the detected amount of dust is equal to or more than a predetermined amount, a measure such as a washing process may be additionally carried out.

When a dust appears after the formation of patterns with a photoresist on a semiconductor substrate, a wafer, or the like, the operation does not proceed to a subsequent process and the photoresist is temporarily removed by using, for example, an organic solvent. Afterward, the application of the photoresist and the formation of patterns may be carried out, such that the manufacturing process may start all over again.

An example of known apparatuses for such visual and defect inspections of wafer is the technology disclosed in Non-Patent Literature 1 presented below.

### CITATION LIST

### Non-Patent Literature

Non-Patent Literature 1: “5. Wafer defect inspection apparatus: semiconductor room: Hitachi High-Tech Corporation” (https://www.hitachi-hightech.com/jp/products/device/semiconductor/inspection.html)

Non-Patent Literature 1 presents one kind of inspection carried out in accordance with whether patterns are formed on wafers. In the case of a patterned wafer inspection apparatus, an image of an area targeted for inspection is captured in accordance with the arrangement of adjacent chips (dies) by using an electron beam or light beam; the image is compared to the image of an adjacent identical pattern or non-defective item. Examples of means for capturing the image include an optical microscope and an electron microscope. In accordance with differences indicated by the comparison results, foreign matters and pattern defects are detected; the detection results are recorded.

In the case of a patternless wafer inspection apparatus, a wafer placed on a rotatable stage is irradiated with a laser beam. The entire area of the wafer is irradiated with the laser beam while the laser beam is relatively moved in the radius direction. In accordance with the state of light scattering, foreign matters and pattern defects are directly detected; alternatively, a detector detects the light scattering. With this configuration, by using, for example, a scanning electron microscope (SEM) visual inspection apparatus, a detection image can be captured.

In any case, with the technology described in Non-Patent Literature 1, details of inspection results are reflected in the manufacturing process of a semiconductor device in accordance with the number and condition of foreign matters, pattern defects, and the like as detection results, and as a result, the inspection results can contribute to the improvement of the yield rate.

### SUMMARY OF THE INVENTION

### Technical Problem

For example, when the amount of dust consisting of foreign matters is equal to or more than a predetermined amount in the visual and defect inspections of wafer carried out in the manufacturing process of a semiconductor device, a measure such as redoing the process after washing or discarding the wafer without performing the subsequent steps of the process is taken.

However, with such a visual inspection method for wafers, when, for example, the amount of dust is equal to or less than the predetermined amount, the process proceeds to a subsequent step without any change. In this case, no problem occurs when dust does not affect device characteristics. However, for example, to manufacture an optoelectronic device that is likely to be affected by dust with respect to the device characteristics, this configuration may cause an undesirable condition.

Specifically, in the case of a compound semiconductor device made of indium phosphide (InP), gallium arsenide (GaAs), or the like, more particularly, an optoelectronic device such as a semiconductor laser, after the semiconductor is subjected to etching, a crystal regrowth step is performed. Also in the case of a quartz optoelectronic device and the like, after waveguide processing, a material is applied to form a layer as a cladding.

In the case of an optoelectronic device, for example, when the optoelectronic device is an optical semiconductor device for communication, the core as the center of propagating light is positioned within about two to four micrometers from a surface of the chip. Thus, when a dust is attached to the optoelectronic device during early steps of the manufacturing process and then covered due to, for example, crystal regrowth, the dust is not detected in visual inspection carried out during later steps of the manufacturing process because it is difficult to view the dust, which causes an undesirable condition in which, for example, a defect exists inside the optoelectronic device.

Further, when the dust is removed due to, for example, etching during the manufacturing process, the existence of dust in some midpoint may later cause an inadequacy such as deformation of the processed shape or changes in the composition of crystal at the time of regrowth of semiconductor crystal.

Usually, in the manufacturing of an optoelectronic device, it is necessary to check the quality during the process before the completion of manufacturing by carrying out various inspections including dust counting by performing the visual inspection described above. After the wafer process is completed and the device is formed into a chip, the quality is finally checked by evaluating electrical and optical device characteristics.

Since it takes relatively long time to carry out the inspections, when an inspection result indicates that a defective item is formed, the manufacturing cost increases in proportion. In particular, in the inspection at the final stage, many kinds of characteristics need to be checked, and chips need to be individually checked; and thus, it tends to take more time. Hence, for the purpose of cost reduction, it is important to evaluate the quality in an inspection as early as possible to avoid characteristic evaluation of a defective item.

As described above, when the known method for manufacturing semiconductor devices, which allows the process to proceed to a subsequent step while dust equal to or less than a predetermined amount remains, is applied to the manufacturing of an optoelectronic device, an inspection for characteristic evaluation is necessary to check the quality under the effect of the remaining dust. When a target item is determined as a defective item at the stage of characteristic evaluation, it is desirable that the cause is specified so as to eliminate the cause in the subsequent manufacturing process. There is, however, a problem in which it is difficult to specify the cause by only viewing the finished chip when the chip contains inside a defect of a dust not easily viewed or a defect caused by a dust removed later, which have been described above.

The present invention has been made to address these problems. A technical object of the present invention is to provide a support apparatus capable of manufacturing an optoelectronic device of improved characteristics efficiently with a low cost and a high yield rate but without inside defects while not performing characteristic evaluation inspection with a measure to deal with defects caused by a small amount of foreign matters.

### Means for Solving the Problem

To achieve the object described above, an optoelectronic device manufacturing apparatus according to an aspect of the present invention includes a defect inspection result acquisition unit configured to acquire inspection result data that represents results obtained by performing a defect inspection in a plurality of steps different from each other and that is outputted by an optoelectronic device inspection apparatus, the defect inspection result acquisition unit being configured to acquire the inspection result data with respect to each of the plurality of steps, the plurality of steps being related to an occurrence of a defect determining a defective item in a primary process composed of steps for manufacturing an optoelectronic device, a database configured to store, with respect to each of the plurality of steps, the inspection result data outputted by the defect inspection result acquisition unit, and a data processing control unit configured to compare information about the defect included in the inspection result data acquired in the plurality of steps of the primary process and reference information representing an inspection result of a normal state and accordingly determining whether an identical defect is indicated, and when a determination result obtained by the determining indicates the identical defect or a change in a state of the defect, store the inspection result data as record data in the database and provide the record data for a subsequent production process composed of steps for manufacturing the optoelectronic device to reflect the record data in the production process.

### Effects of the Invention

With the configuration described above, the present invention can manufacture an optoelectronic device of improved characteristics efficiently with a low cost and a high yield rate but without inside defects while not performing known characteristic evaluation inspection with a measure to deal with defects caused by a small amount of foreign matters.

### BRIEF DESCRIPTION OF DRAWINGS

FIG. 1 is a flowchart illustrating steps of a wafer manufacturing process, which is an example of a primary process composed of steps of an optoelectronic device manufacturing method according to a comparative example.

FIG. 2 is a flowchart illustrating steps of a chip manufacturing process including chip processing of a wafer as an example of a production process composed of steps performed following the primary process illustrated in FIG. 1.

FIG. 3 is a flowchart illustrating steps of a wafer manufacturing process, which is an example of a primary process composed of steps of an optoelectronic device manufacturing method using an optoelectronic device manufacturing support apparatus according to a first embodiment of the present invention.

FIG. 4 is a flowchart illustrating steps of a chip manufacturing process including chip processing of a wafer as an example of a production process composed of steps performed following the primary process illustrated in FIG. 3.

FIG. 5 is a block diagram illustrating a basic configuration of an optoelectronic device manufacturing support apparatus used in the wafer manufacturing process in FIG. 3.

FIG. 6 illustrates a display image formed by performing image processing with respect to information of the position, size, and shape of dust/defect processed by a data processing control unit included in the optoelectronic device manufacturing support apparatus in FIG. 5.

### DESCRIPTION OF EMBODIMENTS

Hereinafter, an optoelectronic device manufacturing support apparatus according to the present invention will be described in detail by presenting an embodiment with reference to the drawings.

Firstly, for ease of understanding of the optoelectronic device manufacturing support apparatus of the present invention, a manufacturing technology according to a comparative example will be described.

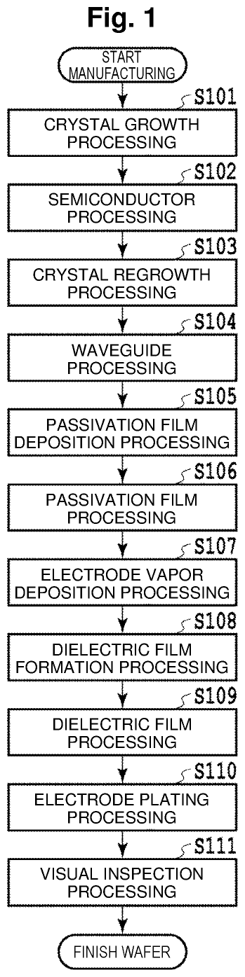

FIG. 1 is a flowchart illustrating steps of a wafer manufacturing process, which is an example of a primary process composed of steps of an optoelectronic device manufacturing method according to the comparative example. The wafer targeted here is a wafer for a semiconductor optical modulator forming a Mach-Zehnder interferometer.

Referring to FIG. 1, in the wafer manufacturing process, a manufacturer starts manufacturing and first carries out crystal growth processing (step S101) in which a crystal of a semiconductor to be formed as a substrate is grown by using silicon, silicon dioxide, or the like as a material. Other examples of the material include indium phosphide (InP) and gallium arsenide (GaAs). Next, in semiconductor processing (step S102), the manufacturer forms the substrate in a desired shape by etching or the like. In crystal regrowth processing (step S103), a crystal is grown again on the processed semiconductor substrate.

Subsequently, in waveguide processing (step S104), the manufacturer coats the upper surface of the substrate with a thin film made of silicon dioxide or the like and forms an optical waveguide in accordance with preset micropatterns. The optical waveguide is formed by covering the core, through which light travels, with a cladding layer. In passivation (insulating) film deposition processing (step S105), an insulating film is deposited to coat the optical waveguide. Subsequently, in passivation (insulating) film processing (step S106), the manufacturer removes an unnecessary part of the insulating film by etching or the like to obtain an area for forming an electrode.

In electrode vapor deposition processing (step S107), the manufacturer forms an electrode by vapor depositing a metal gas or the like at the area for forming an electrode. In dielectric film formation processing (step S108), a dielectric film is formed at an area to be insulated. In dielectric film processing (step S109), an unnecessary part of the dielectric film is removed by etching or the like so as to leave an area to be subjected to electrode plating.

Subsequently, in electrode plating processing (step S110), the allocated area is subjected to electrode plating. Lastly, visual inspection processing (step S111) is performed; as a result, when defects are not serious enough to determine a defective item, the wafer is finished.

For the visual inspection, the patterned wafer inspection apparatus described in Non-Patent Literature 1 can be used. In this manner, the wafer manufacturing process is completed. For example, in a step in which it is expected that dust consisting of foreign matters tends to attach to the wafer so that the resultant defects determine a defective item, the manufacturer counts the amount of dust by visual inspection, and as a result, the process may start all over again. It should be noted that the various processing operations in FIG. 1 can be deemed as a process.

The above description has explained the primary process composed of steps in the optoelectronic device manufacturing method. Hereinafter, a production process composed of steps will be described. The production process is performed following the primary process to finish the optoelectronic device.

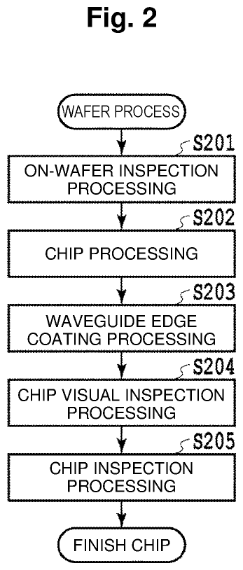

FIG. 2 is a flowchart illustrating steps of a chip manufacturing process including chip processing of the wafer as an example of the production process composed of steps performed following the primary process illustrated in FIG. 1.

Referring to FIG. 2, the chip manufacturing process is performed following the completion of wafer in the wafer manufacturing process described above. Specifically, after the completion of the wafer process, firstly, in on-wafer inspection processing (step S201), the manufacturer evaluates the electrical characteristic of the wafer without any change. As the result of this evaluation, when the wafer is determined as a defective item (fail), the wafer is discarded; when the wafer is a non-defective item, the sections of the wafer having passed the inspection are formed into chips in the subsequent chip processing (step S202).

Subsequently, in waveguide edge coating processing (step S203), the manufacturer coats the edge of the waveguide. In chip visual inspection processing (step S204), the manufacturer visually inspects the exterior of individual chips. As the result of the visual inspection, when a chip is determined as a defective item (fail), the chip is discarded. When the chip is determined as a non-defective item, the chip is further inspected in chip inspection processing (step S205). As the result of this chip inspection, when the chip is determined as a defective item (fail), the chip is discarded; when the chip is determined as a non-defective item, the chip is finished.

Also in these chip visual inspection (step S204) and chip inspection (step S205) as final processing steps, the manufacturer can use, for example, the optical or electron microscope described in Non-Patent Literature 1. Alternatively, various kinds of apparatuses can be used when the apparatuses can evaluate electrical and optical device characteristics. In this manner, the chip manufacturing process is completed. It should be noted that the various processing operations in FIG. 2 can also be deemed as a process.

When the wafer manufacturing process and subsequent chip manufacturing process described above are performed, particularly in the chip manufacturing process, it is necessary to perform characteristic evaluation inspection with a measure to deal with defects caused by foreign matters such as a small amount of dust. Hence, the case in which the electrical characteristic of the wafer without any change is evaluated in early steps of the chip manufacturing process has been described.

However, with such a manufacturing process, it is impossible to manufacture an optoelectronic device efficiently with a low cost and a high yield rate but without inside defects. This is because, as described above as a technical problem, for example, when the amount of dust is equal to or less than a predetermined amount, the process proceeds to a subsequent step. By following such a flow of processing, defects may exist inside due to the effect of a dust not easily viewed or a dust already removed.

It is considered that this problem is caused because, especially in the wafer manufacturing process, defect inspection is not timely carried out in steps in which defects determining a defective item may occur, but visual inspection is carried out at the final stage; in other words, the determination of defective item is carried out in a later stage. In consideration of this problem, a first embodiment described below aims to cope with this problem in a fundamental manner.

### First Embodiment

The present inventors had attempted various examinations, various experiments, and various kinds of research with regard to the wafer manufacturing process and subsequent chip manufacturing process described above, and as a result, the present inventors found that defects determining a defective item mostly occur in the wafer manufacturing process.

Specifically, the present inventors revealed that most of the steps except the dielectric film formation processing (step S108) and the electrode plating processing (step S110) in the wafer manufacturing process illustrated in FIG. 1 affect the occurrence of defect determining a defective item. Accordingly, the present inventors came up with an idea that, by taking a measure to deal with this, it is possible to manufacture an optoelectronic device efficiently with a low cost and a high yield rate but without inside defects; and it is also possible to eliminate characteristic evaluation inspection with a measure taken to cope with defects due to a small amount of foreign matters such as dust.

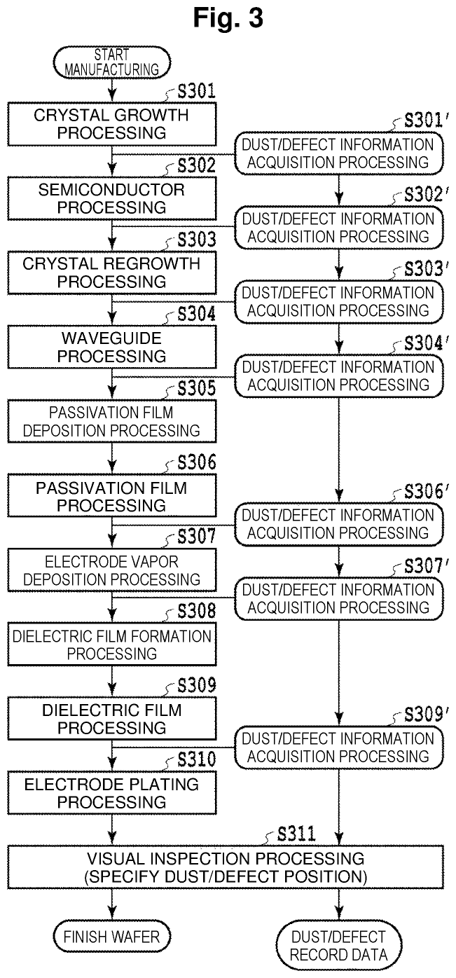

FIG. 3 is a flowchart illustrating steps of a wafer manufacturing process, which is an example of a primary process composed of steps of an optoelectronic device manufacturing method using an optoelectronic device manufacturing support apparatus according to the first embodiment of the present invention. The wafer targeted here is also a wafer for a semiconductor optical modulator forming a Mach-Zehnder interferometer.

Referring to FIG. 3, this wafer manufacturing process is identical to the case illustrated in FIG. 1. and a manufacturer firstly carries out the crystal growth processing (step 301), the semiconductor processing (step S302), and the crystal regrowth processing (step S303). Since details of the processing operations in these steps are identical to that of the crystal growth processing (step 101), the semiconductor processing (step S102), and the crystal regrowth processing (step S103) described with reference to FIG. 1, descriptions thereof are not repeated.

The manufacturer subsequently carries out the waveguide processing (step S304), the passivation (insulating) film deposition processing (step S305), and the passivation (insulating) film processing (step S306). Since details of the processing operations in these steps are identical to that of the waveguide processing (step S104), the passivation film deposition processing (step S105), and the passivation film processing (step S106) described with reference to FIG. 1, descriptions thereof are not repeated.

The manufacturer then carries out the electrode vapor deposition processing (step S307), the dielectric film formation processing (step S308), and the dielectric film processing (step S309). Since details of the processing operations in these steps are identical to that of the electrode vapor deposition processing (step S107), the dielectric film formation processing (step S108), and the dielectric film processing (step S109) described with reference to FIG. 1, descriptions thereof are not repeated.

Additionally, the electrode plating processing (step S310) and the visual inspection processing (step S311) are carried out. Since details of the processing operations in these steps are almost identical to that of the electrode plating processing (step S110) and the visual inspection processing (step S111) described with reference to FIG. 1, descriptions thereof are not repeated. However, details of the processing operation of the visual inspection processing (step S311) are partially different from the visual inspection processing (step S111), and the different part will be described later.

The fundamental difference between the flow of processing in FIG. 1 and the flow of processing in FIG. 3 is that, in the flow of processing in FIG. 3, dust/defect information acquisition processing, which is processing of specifying the position of dust/defect, is performed multiple times between the steps before the wafer is finished. The dust/defect information acquisition processing is performed by using an optoelectronic device inspection apparatus which outputs inspection result data of results obtained by performing defect inspection in a plurality of steps different from each other that may relate to the occurrence of defect determining a defective item in the primary process composed of steps for manufacturing an optoelectronic device.

It is preferable that the optoelectronic device inspection apparatus have a function of outputting one or more kinds of data obtained by performing image processing with respect to one or more kinds of defect information including at least the position of defect as necessary information, and the size of defect and the shape of defect. A scanning electron microscope (SEM) exemplifies the optoelectronic device inspection apparatus.

Examples of application include the dust/defect information acquisition processing (step S301′) performed immediately after the crystal growth processing (step S301) and the dust/defect information acquisition processing (step S302′) performed immediately after the semiconductor processing (step S302). Examples of application also include the dust/defect information acquisition processing (step S303′) performed immediately after the crystal regrowth processing (step S303).

Examples of application further include the subsequent dust/defect information acquisition processing (step S304′) performed immediately after the waveguide processing (step S304) and the dust/defect information acquisition processing (step S305′) performed immediately after the passivation (insulating) film deposition processing (step S305). Examples of application also include the dust/defect information acquisition processing (step S306′) performed immediately after the passivation (insulating) film processing (step S306).

Examples of application further include the subsequent dust/defect information acquisition processing (step S307′) performed immediately after the electrode vapor deposition processing (step S307) and the dust/defect information acquisition processing (step S309′) performed immediately after the dielectric film processing (step S309).

Results obtained in the dust/defect information acquisition processing (steps S301′, S302′, S303′, S304′, S305′, S306′, S307′, and S309′) are sent to a manufacturing support apparatus, which will be described later, after the visual inspection processing (step S311).

Specifically, a data processing control unit included in the manufacturing support apparatus processes data so that the position of dust/defect is specified, and dust/defect record data is outputted in the visual inspection processing (step S311). This means that the specification of the position of dust/defect and the generation of the dust/defect record data are implemented by using the data processing function of the data processing control unit.

The data processing control unit compares dust/defect information included in the inspection result data obtained in a plurality of steps different from each other of the primary process and sent from the optoelectronic device inspection apparatus and reference information representing an inspection result indicating the normal state. By doing this comparison, it is determined whether an identical dust/defect is indicated. When this determination result indicates an identical dust/defect or a change in the state of a dust/defect, the inspection result data at this time is provided as the record data for a subsequent production process to reflect the inspection result data in the subsequent production process.

It is preferable that an image obtained in advance by imaging a particular wafer as a non-defective item be used as the reference information. It is also possible to use an image obtained in a particular step in which no inferior part is discovered by the inspection. Both the dust/defect information and the reference information are included in the inspection result data.

In the wafer manufacturing process illustrated in FIG. 3, attention is focused on the time before and after steps in which it is likely to become difficult to view the dust/defect or the dust/defect is likely to disappear, especially such as the time before and after etching for processing the semiconductor, the time before and after crystal regrowth, and the time before and after the formation of the electrode. The optoelectronic device inspection apparatus specifies the position and size of a defect as the dust/defect information by performing imaging, image recognition, and the like. To discover the dust/defect from an image, as described above, the inspection image can be compared to a reference image of a non-defective item serving as the reference information.

Laser scattering or any method other than image recognition can be applied to the optoelectronic device inspection apparatus when the position of dust/defect can be specified by using the method. To specify the position of dust/defect, an absolute value on the wafer (flat surface of the wafer) or a preformed pattern is used as a reference. For example, a positioning mark, which is usually formed at the start of the wafer manufacturing process, can be used as a reference.

When images are used to detect a dust/defect, high magnification images are captured to image the optical waveguide. However, depending on the function of capturing an image, the position of dust/defect may considerably differ due to, for example, the error of movement of the stage. In such a case, it is possible to use, for example, a preformed pattern of waveguide as a reference. In this case, by obtaining information about mask design for lithography, the position in the wafer (also in the chip) can be specified.

In any case, by comparing different steps with respect to the position of dust/defect and also comparing the dust/defect information with the reference information, it is possible to identify a particular step in which the dust/defect is mixed in or caused. When dust is removed by etching or the like, it is also possible to identify a particular step in which the dust disappears.

The manufacturer compares, with respect to a plurality of steps, the position of dust/defect and the reference information so that the manufacturer determines whether an identical dust/defect is indicated; in this manner, the accuracy can be increased and in addition to the position, by obtaining the size and shape of dust/defect, the determination can be more accurate. When the locating precision range of dust/defect is equal to or less than the size of dust/defect, the coordinates of detected positions of dust/defect at least partially coincide, and accordingly, it is possible to easily assume that an identical dust/defect is indicated.

By contrast, it is assumed that, for example, the size of dust/defect is a diameter of about 1 micrometer and the locating precision range is 2 to 3 micrometers, which is double to triple the size of dust/defect. In this case, by additionally using information about shape or the like and information about a step performed between the compared images, the manufacturer can assume whether an identical dust/defect is indicated.

As described above, since the dust/defect record data is obtained by performing the determination of the position of dust/defect multiple times, it is unnecessary to determine the position of defect in the final product form. This is because, with respect to the product, it is possible to previously obtain records regarding whether the dust/defect likely to affect device characteristics exist.

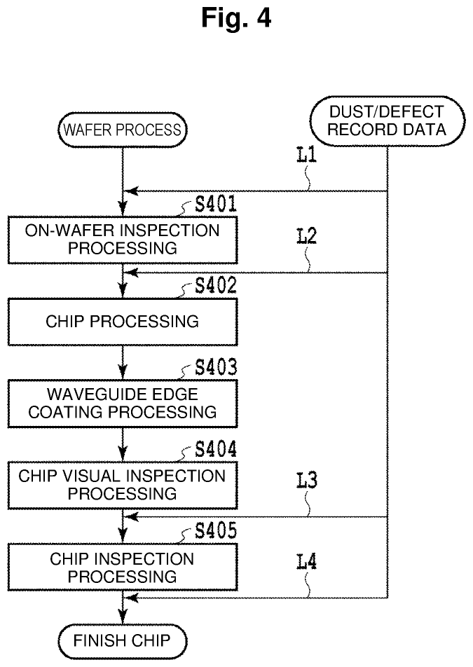

FIG. 4 is a flowchart illustrating steps of a chip manufacturing process including chip processing of the wafer as an example of the production process composed of steps performed following the primary process illustrated in FIG. 3.

Referring to FIG. 4, in this chip manufacturing process, as in the case illustrated in FIG. 2, firstly, the on-wafer inspection processing (step 401), the chip processing (step S402), and the waveguide edge coating processing (step S403) are performed. Since details of the processing operations in these steps are identical to that of the on-wafer inspection processing (step 201), the chip processing (step S202), and the waveguide edge coating processing (step S203) described with reference to FIG. 2, descriptions thereof are not repeated.

Lastly, the chip visual inspection processing (step S404) and the chip inspection processing (step S405) are performed. Since details of the processing operations in these steps are also identical to that of the chip visual inspection processing (step S204) and the chip inspection processing (step S205) described with reference to FIG. 2, descriptions thereof are not repeated.

The fundamental difference between the flow of processing in FIG. 4 and the flow of processing in FIG. 2 is that, as illustrated in FIG. 4, the quality of device is checked by inspection in accordance with the dust/defect record data outputted by specifying the position of dust/defect in the preceding visual inspection processing (step S311). Specifically, the dust/defect record data is provided for steps before and after the on-wafer inspection processing (step 401) and steps before and after the chip inspection processing (step S405).

Specifically, the dust/defect record data transmitted to a signal line L1 before the on-wafer inspection processing (step 401) is used to determine a region for performing on-wafer inspection. The dust/defect record data transmitted to a signal line L2 after the on-wafer inspection processing (step 401) is used to determine a device to be formed in a chip.

The dust/defect record data transmitted to a signal line L3 before the chip inspection processing (step S405) is used to determine a chip to be inspected. The dust/defect record data transmitted to a signal line L4 after the chip inspection processing (step S405) is used for the final quality evaluation.

By performing the wafer manufacturing process illustrated in FIG. 3 and the chip manufacturing process illustrated in FIG. 4, various assumptions can be made as described below.

For example, in the case in which a dust/defect exists at a position adjacent to the waveguide or the waveguide has a break after the waveguide processing, it can be easily assumed that the optical propagation loss increases although the waveguide cannot be directly viewed after the formation of the electrode and the formation of the dielectric film.

In the case in which before crystal regrowth a dust/defect exists in an area at which a waveguide is to be formed in a subsequent step, after the dust/defect is covered due to the crystal regrowth, the manufacturer can easily assume that a defect exists inside. By contrast, in the case in which a dust exists in a chip, when the dust does not overlap the waveguide, the electrode, and the like, it is unnecessary to determine the device containing the dust as a defective item because the dust does not cause any problem with respect to device characteristics.

When a foreign matter is discovered in the final visual inspection, it is sometimes difficult to determine whether, for example, the foreign matter exists over or under the electrode. However, obtaining the dust/defect record data enables such determination. Accordingly, when the foreign matter is, for example, a dust over the electrode, it can be determined that the foreign matter does not affect device characteristics and reliability.

In addition to the position of dust/defect, the size and shape of dust/defect may be useful for the determination of effects on device characteristics. For example, in the case of crystal regrowth, a large dust affects a wider range than that of a small dust. Due to the surface orientation of crystal, the crystal face appearing when a dust/defect is covered and the surface orientation appearing because of etching are changed in accordance with the shape of dust/defect.

As described above, when an optoelectronic device is determined as a defective item in accordance with the inspection result data obtained by the optoelectronic device inspection apparatus and the dust/defect record data based on the inspection result data, the manufacturer can remove the defective item without performing characteristic evaluation after visual inspection of the wafer. Consequently, it is possible to reduce the inspection cost in proportion. When the quality cannot be clearly evaluated in accordance with only the dust/defect information, it is possible to more accurately evaluate the quality by using a result of characteristic evaluation.

Device characteristics usually indicate a distribution in a certain range centered around a typical value. When the distribution is affected by a dust/defect, the range of the affected distribution does not coincide with the range of the distribution of a proper item; and based on this, it can be concluded that the corresponding device is a defective item. Conversely, to prevent defective items from being distributed, non-defective items apart from the typical value of the distribution are usually discarded in consideration of risk, and as a result, the manufacturing cost increases in proportion.

In this respect, since the first embodiment enables proper quality evaluation, it is possible to decrease the degree to which non-defective items are discarded, and as a result, the reduction of costs can be achieved.

In accordance with the dust/defect record data, an inspection engineer determines whether a particular dust/defect affects device characteristics and reliability. By using the determination result as training data, machine learning may be performed and the determination may be accordingly carried out with the use of artificial intelligence.

In some cases, it may be difficult for the inspection engineer to carry out the determination in accordance with the inspection result data obtained by the optoelectronic device inspection apparatus and the dust/defect record data based on the inspection result data; in other words, the condition may be so unclear that the determination varies among people. For this case, it is effective to previously establish determination criteria by analyzing both results about device characteristics and dust/defect information.

It should be noted that, while in the first embodiment described above information necessary for the inspection result data from an optoelectronic device inspection apparatus 11 is described as the dust/defect information, it is problematic that in practice a dust as a foreign matter is determined as a defect. Hence, technically, data about a foreign matter resulting in a defect can be practically regarded as defect information. In particular, as described above, the position of defect is essential as an important piece of the defect information. Hereinafter, the dust/defect record data is referred to as record data when appropriate.

In any case, the manufacturing method according to the first embodiment is notably effective especially in manufacturing optical devices. In an optical device, when even one dust/defect causing a defect exists at an optical waveguide, this causes the optical loss, resulting in marked characteristic degradation. For this reason, it is important to locate each dust/defect and obtain the record data of each dust/defect. This manufacturing method can be applied to not only semiconductor optical devices but also optical devices made of quartz and optical devices and the like made of organic materials or other materials.

In other words, this manufacturing method is also effective in manufacturing electronic devices and the like when the device is formed on a substrate, and when a dust/defect appears in the manufacturing process or a dust/defect appears and later disappears, and only one dust/defect causes a large effect. This manufacturing method can also be applied to, for example, liquid crystal monitors made by interposing a liquid crystal layer between substrates.

While in the first embodiment the defect inspection (dust/defect information acquisition processing) is performed seven times during the manufacturing process of optoelectronic device in the example of the wafer manufacturing process illustrated in FIG. 3, this number should not be construed in a limiting sense. The number of times that the defect inspection is performed can be selectively set by determining the level of interest of each step in accordance with the basic structure of the optoelectronic device and the manufacturing process of the optoelectronic device.

This means that the number of time that the defect inspection is performed can be decreased or increased. It is only necessary to perform processing for locating the dust/defect at least twice and determine whether any dust/defect has been mixed in. As a result, the condition of dust/defect can be determined when the effect of the dust/defect on device characteristics cannot be determined in accordance with only the finished exterior appearance, which enables quality determination or serves as a supplementary material for quality determination.

To determine whether an identical dust/defect is indicated with the use of the data processing control unit, every time the position of dust/defect is specified in the primary process of the manufacturing process, the position of dust/defect in one step may be compared to the position of dust/defect in a preceding step. Alternatively, the position of dust/defect can be successively specified in the steps of the primary process of the manufacturing process, and then, the comparison processing may be performed together with respect to all the steps. Alternatively, for example, the comparison processing may be performed every two or three steps when the position of dust/defect is specified. Such a setting can be flexibly configured in consideration of the time required for the primary process, the processing time required to specify the position of dust/defect, and the like.

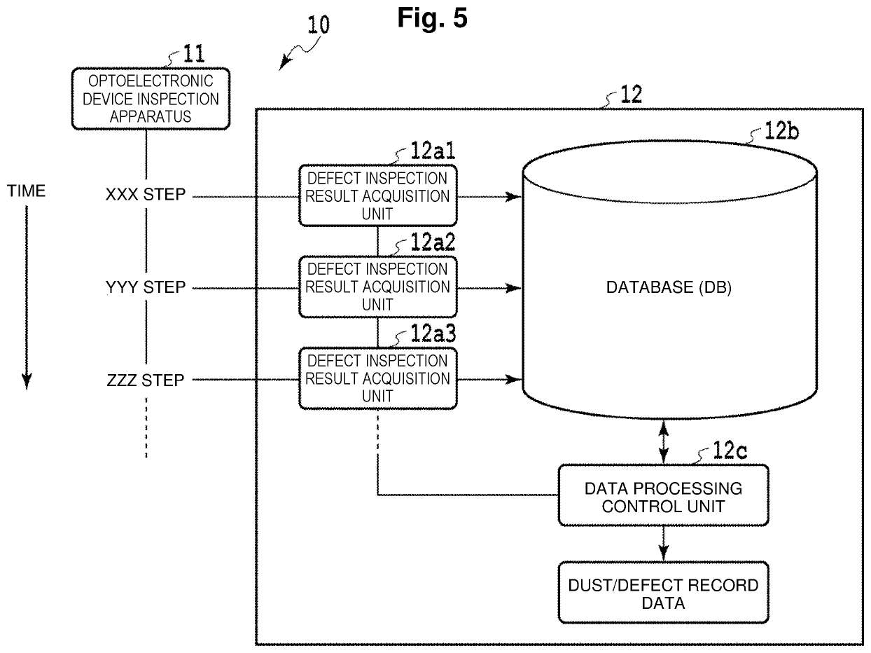

FIG. 5 is a block diagram illustrating a basic configuration of an optoelectronic device manufacturing support apparatus according to the first embodiment of the present invention.

Referring to FIG. 5, the optoelectronic device manufacturing support apparatus is constituted by a server 12 configured to receive the inspection result data outputted by the optoelectronic device inspection apparatus 11. The optoelectronic device inspection apparatus 11 outputs the inspection result data of results obtained by performing defect inspection in a plurality of preset steps different from each other that may relate to the occurrence of defect determining a defective item in the primary process composed of steps relating to the optoelectronic device manufacturing process. The server 12 includes defect inspection result acquisition units 12a1, 12a2, and 12a3, a database (DB) 12b, and a data processing control unit 12c.

The defect inspection result acquisition units 12a1, 12a2, and 12a3 of the server 12 acquire, for a plurality of steps, the inspection result data of each step from the optoelectronic device inspection apparatus 11 by being controlled by the data processing control unit 12c. The database 12b stores the inspection result data of each step outputted by the defect inspection result acquisition units 12a1, 12a2, and 12a3 by being controlled by the data processing control unit 12c.

By comparing defect information included in the inspection result data obtained in the plurality of steps of the primary process and the reference information indicating the inspection result of the normal state, the data processing control unit 12c determines whether an identical defect is indicated. When the determination result indicates an identical defect or a change in the state of a defect, the inspection result data at this time is stored in the database 12b as the record data, and the record data is provided for the subsequent production process composed of steps for manufacturing an optoelectronic device to reflect the record data in the production process.

As described above as an example, the primary process here denotes the wafer manufacturing process and the production process denotes the chip manufacturing process including the chip processing of the wafer. Thus, it is preferable that the data processing control unit 12c provide the record data for steps before and after the device inspections in the chip manufacturing process.

Since the device inspections denote the on-wafer inspection and the final chip inspection, the record data is provided for steps before and after the on-wafer inspection and the final chip inspection. As described above, it is preferable that the optoelectronic device inspection apparatus 11 have a function of outputting one or more kinds of data by performing image processing with respect to one or more kinds of defect information including at least the position of defect as necessary information, and the size of defect and the shape of defect.

While in the wafer manufacturing process the flow of steps of acquiring the dust/defect information proceeds, for example, from XXX step, to YYY step, and to ZZZ step, the optoelectronic device inspection apparatus 11 outputs the dust/defect information in each step. This means that the optoelectronic device inspection apparatus 11 sends the inspection result data obtained in XXX step, YYY step, and ZZZ step sequentially to the respective defect inspection result acquisition units 12a1, 12a2, and 12a3 of the server 12.

The dust/defect information includes the position of dust/defect, and also the size and shape of dust/defect. Part or all of the dust/defect information is obtained and separately inputted to the server 12. In the dust/defect information, the position of dust/defect is necessary information, but the size and shape of dust/defect are not necessarily used.

In the server 12, the database 12b stores the dust/defect information obtained in each step individually for the step. Subsequently, in the server 12, the data processing control unit 12c determines whether an identical dust/defect is indicated by comparing the dust/defect information of different steps and the reference information.

When the determination result indicates an identical dust/defect or a change in the state of a dust/defect, the data processing control unit 12c stores the inspection result data at this time as the record data in the database 12b. At the same time, the record data is provided for steps before and after the device inspections (on-wafer inspection and chip inspection) in the production process composed of steps for manufacturing an optoelectronic device to reflect the record data in the device inspections.

The outputted record data identifies particular steps between which a dust/defect appears or disappears. The detection function of the optoelectronic device inspection apparatus 11 of detecting and outputting the dust/defect information in each step of the wafer manufacturing process and the function of outputting the dust/defect record data processed by the data processing control unit 12c of the server 12 are combined with each other. The configuration formed by combining the optoelectronic device inspection apparatus 11 and the server 12 serving as the optoelectronic device manufacturing support apparatus with each other may be referred to as an optoelectronic device manufacturing support system 10.

This combination implements a function of supporting the manufacture of an optoelectronic device with the use of the server on the basis that the inspection result data obtained by performing inspections in a plurality of steps different from each other and outputted by the optoelectronic device inspection apparatus 11 is acquired. To detect the position of dust/defect by using the optoelectronic device inspection apparatus 11, the dust/defect information and the reference information, which is the image of a non-defective item of the wafer during the process, can be compared to each other.

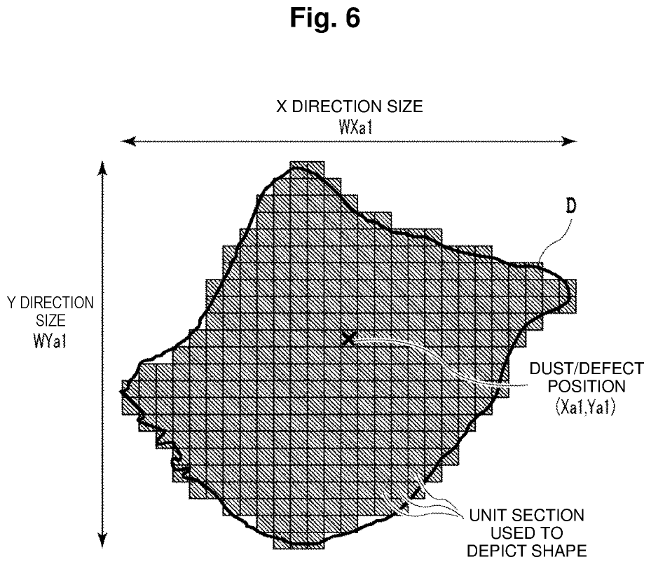

FIG. 6 illustrates a display image formed by performing image processing with respect to information of the position, size, and shape of dust/defect processed by the data processing control unit 12c included in the server 12 constituting the optoelectronic device manufacturing support apparatus.

Referring to FIG. 6, for example, it is assumed that the first dust/defect examined by the inspection in XXX step is the X direction size of WXa1 and the Y direction size of WYa1. The center position is specified as a dust/defect position (Xa1, Ya1). To represent the shape of a dust D by data, for example, the dust/defect can be sectioned in accordance with a unit area, and coordinates of each unit section are collectively specified as a coordinate group.

In any case, the optoelectronic device inspection apparatus obtains one or more kinds of defect information including at least the position of defect as necessary information, and the size of defect and the shape of defect by performing image processing, and as a result, representations of these kinds of data can be displayed on a monitor screen of the server 12.

Additionally, these kinds of data can be transferred to a terminal device and representations of the data can be displayed on a screen of the terminal device. These kinds of data can also be stored in the form of table in the database 12b. Specifically, the database 12b can store as the defect information of each step one or more kinds of data including at least coordinates of the position of defect as necessary information, and directions regarding the size of defect and a coordinate group regarding the shape of defect in the form of table.

The representations illustrated in FIG. 6 are an example of data for storage in the database 12b, but other kinds of definitions can be used. For example, coordinates of a unit section used to record the shape of the dust D may be instead expressed as a vector from the position of defect.

Table 1 is an example of a data set of the dust/defect information obtained in accordance with the definitions in FIG. 6.

TABLE 1

| | Position | | Size | | |
|---|---|---|---|---|---|
| | X | Y | X | Y | Shape |
| Number | coordinate | coordinate | direction | direction | Coordinate group |
| Step A | | | | | |
| 1 | Xa1 | Ya1 | WXa1 | WYa1 | S1 (Xa11, Ya11, Xa12, Ya12, . . .) |
| 2 | Xa2 | Ya2 | WXa2 | WYa2 | S2 (Xa21, Ya21, Xa22, Ya22, . . .) |
| 3 | Xa3 | Ya3 | WXa3 | WYa3 | S3 (Xa31, Ya31, Xa32, Ya32, . . .) |
| 4 | Xa4 | Ya4 | WXa4 | WYa4 | S4 (Xa41, Ya41, Xa42, Ya42, . . .) |
| 5 | Xa5 | Ya5 | WXa5 | WYa5 | S5 (Xa51, Ya51, Xa52, Ya52, . . .) |
| Step B | | | | | |
| 1 | Xb1 | Yb1 | WXb1 | WYb1 | S1 (Xb11, Yb11, Xb12, Yb12, . . .) |
| 2 | Xb2 | Yb2 | WXb2 | WYb2 | S2 (Xb21, Yb21, Xb22, Yb22, . . .) |
| 3 | Xb3 | Yb3 | WXb3 | WYb3 | S3 (Xb31, Yb31, Xb32, Yb32, . . .) |
| 4 | Xb4 | Yb4 | WXb4 | WYb4 | S4 (Xb41, Yb41, Xb42, Yb42, . . .) |
| 5 | Xb5 | Yb5 | WXb5 | WYb5 | S5 (Xb51, Yb51, Xb52, Yb52, . . .) |
| Step C | | | | | |
| 1 | Xc1 | Yc1 | WXc1 | WYc1 | S1 (Xc11, Yc11, Xc12, Yc12, . . .) |
| 2 | Xc2 | Yc2 | WXc2 | WYc2 | S2 (Xc21, Yc21, Xc22, Yc22, . . .) |
| 3 | Xc3 | Yc3 | WXc3 | WYc3 | S3 (Xc31, Yc31, Xc32, Yc32, . . .) |
| 4 | Xc4 | Yc4 | WXc4 | WYc4 | S4 (Xc41, Yc41, Xc42, Yc42, . . .) |
| 5 | Xc5 | Yc5 | WXc5 | WYc5 | S5 (Xc51, Yc51, Xc52, Yc52, . . .) |

Table 1 indicates an example of a data set in which XXX step, YYY step, and ZZZ step are respectively indicated as step A, step B, and step C, and position, size, and shape are listed in association with data number in accordance with the dust/defect information obtained by inspection in each step. In practice, five or more dusts/defect may be examined; but here, for ease of description, only five pieces of data are listed in each step.

As described with reference to FIG. 6, in Table 1, the field of position includes X coordinate and Y coordinate, the field of size includes X direction and Y direction, and the field of shape includes coordinate group. To differentiate among step A, step B, and step C, each data item additionally contains one small letter of a, b, and c.

Table 2 is an example of an output data set as the record data by constructing a data set by using the determination result of whether an identical dust/defect is indicated and the change in the state of the dust/defect processed with the use of the data processing control unit 12c of the optoelectronic device manufacturing support system 10 in accordance with the data set of Table 1.

TABLE 2

| | Step A (position, size, shape) | | | | |
|---|---|---|---|---|---|
| | Position | | Size | | |
| | X | Y | X | Y | Shape |
| # | coordinate | coordinate | direction | direction | Coordinate group |
| 1 | Xa1 | Ya1 | WXa1 | WYa1 | Sa1 (Xa11, Ya11, Xa12, Ya12, . . .) |
| 2 | Xa2 | Ya2 | WXa2 | WYa2 | Sa2 (Xa21, Ya21, Xa22, Ya22, . . .) |
| 3 | Xa3 | Ya3 | WXa3 | WYa3 | Sa3 (Xa31, Ya31, Xa32, Ya32, . . .) |
| 4 | Xa4 | Ya4 | WXa4 | WYa4 | Sa4 (Xa41, Ya41, Xa42, Ya42, . . .) |
| 5 | Xa5 | Ya5 | WXa5 | WYa5 | Sa5 (Xa51, Ya51, Xa52, Ya52, . . .) |
| 6 | | | | | |
| 7 | | | | | |
| 8 | | | | | |
| 9 | | | | | |
| 10 | | | | | |

Step B (position, size, shape)

| | | |
|---|---|---|
| Position | Size | Shape |

| X | Y | X | Y | Coordinate |
|---|---|---|---|---|
| coordinate | coordinate | direction | direction | group (omitted) |
| Xb1 | Yb1 | WXb1 | WYb1 | Sb1 |
| Xb2 | Yb2 | WXb2 | WYb2 | Sb2 |
| Xb3 | Yb3 | WXb3 | WYb3 | Sb3 |
| Xb4 | Yb4 | WXb4 | WYb4 | Sb4 |
| Xb5 | Yb5 | WXb5 | WYb5 | Sb5 |

| Step C (position, size, shape) | | | | | | |
|---|---|---|---|---|---|---|
| Position | | Size | | Shape | | |
| X | Y | X | Y | Coordinate | | |
| coordinate | coordinate | direction | direction | group (omitted) | Appearance | Disappearance |
| Xc1 | Yc1 | WXc1 | WYc1 | Sc1 | A | |
| | | | | | A | B |
| Xc2 | Yc2 | WXc2 | WYc2 | Sc2 | A | |
| | | | | | A | C |
| Xc3 | Yc3 | WXc3 | WYc3 | Sc3 | A | |
| Xc4 | Yc4 | WXc4 | WYc4 | Sc4 | B | |
| Xc5 | Yc5 | WXc5 | WYc5 | Sc5 | C | |

Also in Table 2, XXX step, YYY step, and ZZZ step are respectively indicated as step A, step B, and step C; a step in which an identical dust/defect is discovered is indicated in the field of appearance, and a step in which the state of the dust/defect is changed is indicated in the field of disappearance.

The determination of whether a dust/defect examined in step A is identical to a dust/defect examined in step B in accordance with the inspection results is performed by following, for example, first to third procedures described below. The first procedure is to determine whether the position of dust/defect is identical. The second procedure is to determine whether the dust in step A and the dust in step B overlap with respect to the X coordinate of the position of dust/defect±half of the X direction size and the Y coordinate of the position of dust/defect±half of the Y direction size. The third procedure is to determine whether the dust in step A and the dust in step B overlap with respect to the coordinate group of the shape of dust/defect.

By following this method, the first procedure cannot deal with the case in which the position of dust/defect varies due to the error of coordinate measurement method and the size of dust or defect may accordingly alter in some steps. Hence, in this case, the second or third procedure is performed for the determination.

In Table 2, a dust/defect is determined to appear in the second data record of step A, but the identical dust/defect is not listed in the second data record of step B. Needless to say, the identical dust/defect is also not listed in the second data record of step C. Accordingly, as for the second data record, A is indicated in the field of appearance and B is indicated in the field of disappearance. By contrast, a dust/defect is determined to appear in the fourth data record of step A; the identical dust/defect still remains in the fourth data record of step B but is not listed in the fourth data record of step C. Accordingly, as for the fourth data record, A is indicated in the field of appearance and C is indicated in the field of disappearance.

The present invention is not limited to the embodiment described above, various modifications can be made without departing from the technical scope, and all technical matters included in the technical idea described in the claims are embodied in the subject of the present invention. The embodiment described above is one preferable example, and those skilled in the art can develop various modified examples by using the disclosed details. In this case, the various modified examples are also embraced in the claims.

### REFERENCE SIGNS LIST

10 Optoelectronic device manufacturing support system
11 Optoelectronic device inspection apparatus
12 Server
12a1, 12a2, 12a3 Defect inspection result acquisition unit
12b Database (DB)
12c Data processing control unit
D Dust
L1, L2, L3, L4 Signal line

1. An optoelectronic device manufacturing support apparatus comprising:
a defect inspection result acquisition unit configured to acquire inspection result data that represents results obtained by performing a defect inspection in a plurality of steps different from each other and that is outputted by an optoelectronic device inspection apparatus, the defect inspection result acquisition unit being configured to acquire the inspection result data with respect to each of the plurality of steps, the plurality of steps being related to an occurrence of a defect determining a defective item in a primary process composed of steps for manufacturing an optoelectronic device;
a database configured to store, with respect to each of the plurality of steps, the inspection result data outputted by the defect inspection result acquisition unit; and
a data processing control unit configured to
compare information about the defect included in the inspection result data acquired in the plurality of steps of the primary process and reference information representing an inspection result of a normal state and accordingly determining whether an identical defect is indicated, and
when a determination result obtained by the determining indicates the identical defect or a change in a state of the defect, store the inspection result data as record data in the database and provide the record data for a subsequent production process composed of steps for manufacturing the optoelectronic device to reflect the record data in the production process.

2. The optoelectronic device manufacturing support apparatus according to claim 1, wherein
the primary process is a wafer manufacturing process of a wafer,
the production process is a chip manufacturing process including chip processing of the wafer, and
the data processing control unit is configured to provide the record data for steps before and after an on-wafer inspection for evaluating an electrical characteristic of the wafer without any change and steps before and after a final chip inspection after the wafer is subjected to the chip processing, the on-wafer inspection and the final chip inspection being a device inspection in the chip manufacturing process.

3. The optoelectronic device manufacturing support apparatus according to claim 1, wherein
the defect inspection result acquisition unit is configured to acquire, as the information about the defect from the optoelectronic device inspection apparatus, one or more kinds of data outputted by performing image processing with respect to one or more kinds of information including at least a position of the defect as necessary information, and additionally any of a size of the defect and a shape of the defect.

4. The optoelectronic device manufacturing support apparatus according to claim 3, wherein
the database is configured to store, as the information about the defect in each of the plurality of steps, one or more kinds of data including at least coordinates of the position of the defect as necessary information, and directions regarding the size of the defect and a coordinate group regarding the shape of the defect in a form of table.

5. The optoelectronic device manufacturing support apparatus according to claim 2, wherein
the defect inspection result acquisition unit is configured to acquire, as the information about the defect from the optoelectronic device inspection apparatus, one or more kinds of data outputted by performing image processing with respect to one or more kinds of information including at least a position of the defect as necessary information, and additionally any of a size of the defect and a shape of the defect.
